(19) United States
(12) Patent Application Publication
(10) Pub. No.: US 2026/0304706 A1
(43) Pub. Date: Oct. 1, 2026

(54) ELECTRONIC DEVICE AND TEMPERATURE CONTROL METHOD

(71) Applicant: Smarter Silicon (Shanghai) Technologies Co., Ltd., Shanghai (CN)

(72) Inventors: Qian LIU, Shanghai (CN); Xiawen CHEN, Shanghai (CN); Junjie XU, Shanghai (CN)

(21) Appl. No.: 19/679,178

(22) Filed: May 15, 2026

Related U.S. Application Data
(63) Continuation of application No. PCT/CN2024/121628, filed on Sep. 27, 2024.

(30) Foreign Application Priority Data
Nov. 30, 2023 (CN) 202311634935.0

(51) Int. Cl. H05K 7/20

(52) U.S. Cl. CPC H05K 7/2039

(57) ABSTRACT

An electronic device includes a housing, a functional assembly arranged in the housing, a heat dissipation assembly. The heat dissipation assembly is configured to transfer heat of the functional assembly to the housing, and has a gap with the housing, and moves relative to the housing to cause the gap between the heat dissipation assembly and the housing to change. The device further includes a control module configured to control the heat dissipation assembly to move to adjust the gap between the heat dissipation assembly and the housing based on a feedback of a temperature of the housing and a temperature of the functional assembly.

### CROSS-REFERENCE TO RELATED APPLICATIONS

The present application is a continuation of International Application No. PCT/CN 2024/121628, filed on Sep. 27, 2024, which claims priority to Chinese Patent Application No. 202311634935.0, filed on Nov. 30, 2023, the entire contents of both of which are incorporated herein by reference.

### TECHNICAL FIELD

The present disclosure relates to the electronic device technology field and, more particularly, to an electronic device and a temperature control method.

### BACKGROUND

When an electronic device (such as tablets or cell phones) is in operation, heat generated by a functional assembly (such as a chip) is transferred to a housing (such as a display assembly) through a heat dissipation assembly. The temperature of the functional assembly needs to be within a specified range, and the temperature of the housing should not exceed a certain threshold. That is, the performance of the functional assembly needs to be ensured while the user experience is satisfied. The temperatures of the functional assembly and the housing rise differently under different scenarios. For example, in a scenario of heavy load, the temperature of the housing first reaches the threshold, and the temperature of the functional assembly still has a certain room to rise. Thus, the performance of the functional assembly is limited, which impacts the user experience. In another example, in a benchmarking performance scenario, the instant temperature rise is large. The temperature of the functional assembly first reaches the threshold while the temperature of the housing has a certain room to rise, which triggers the functional assembly to perform temperature control and reduce frequency.

### SUMMARY

The present disclosure provides an electronic device including a housing, a functional assembly arranged in the housing, a heat dissipation assembly, and a drive module. The heat dissipation assembly is configured to transfer heat of the functional assembly to the housing, and has a gap with the housing, and moves relative to the housing to cause the gap between the heat dissipation assembly and the housing to change. The control module is configured to control the heat dissipation assembly to move to adjust the gap between the heat dissipation assembly and the housing based on a feedback of a temperature of the housing and a temperature of the functional assembly.

The present disclosure provides a temperature control method applied to an electronic device. The method includes monitoring a temperature of the housing and a temperature of the functional assembly, in response to the temperature of the housing reaching a first threshold, and the temperature of the functional assembly being smaller than a second threshold, controlling a heat dissipation assembly to move away from a housing of the electronic device or trigger the housing to perform temperature control to maintain the temperature of the housing to be lower than the first threshold, and in response to the temperature of the functional assembly being greater than or equal to the second threshold, and the temperature of the housing being smaller than the first threshold, controlling the heat dissipation assembly to move toward the housing or adjust an operation state of the functional assembly to maintain the temperature of the functional assembly to be lower than the second threshold.

### BRIEF DESCRIPTION OF THE DRAWINGS

FIG. 1 illustrates a schematic structural diagram of an electronic device according to some embodiments of the present disclosure.

FIG. 2 illustrates a schematic structural diagram of another electronic device according to some embodiments of the present disclosure.

### REFERENCE NUMERALS

1 Housing
2 Functional assembly
3 Heat dissipation assembly
31 First heat dissipation body
32 Second heat dissipation body
34 Drive module
4 Carrier

### DETAILED DESCRIPTION OF THE EMBODIMENTS

The technical solutions of embodiments of the present disclosure are described in detail in connection with the accompanying drawings of embodiments of the present disclosure. Obviously, the described embodiments are merely some embodiments of the present disclosure, not all embodiments. Based on embodiments of the present disclosure, all other embodiments obtained by those skilled in the art without creative efforts are within the scope of the present disclosure.

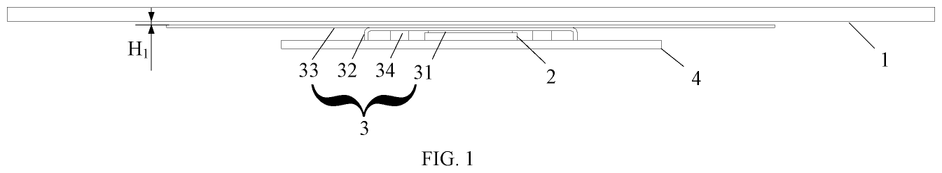

As shown in FIG. 1, an electronic device of embodiments of the present disclosure includes a housing 1, a functional assembly 2 arranged in the housing 1 of the electronic device, a heat dissipation assembly 3, and a control module.

The heat dissipation assembly 3 can be configured to transfer the heat of the functional assembly 2 to the housing 1. The heat dissipation assembly 3 has a gap with the housing 1, and the heat dissipation assembly 3 is movable relative to the housing 1 to allow the gap between the heat dissipation assembly 3 and the housing 1 to change.

The control module can be configured to control the movement of the heat dissipation assembly 3 based on feedback of the temperature of the housing and the temperature of the functional assembly to adjust the gap between the heat dissipation assembly 3 and the housing 1.

The housing 1 can be a display assembly of a large-screen electronic device (such as a tablet or cell phone), or a housing of a conventional electronic device. For the large-screen electronic device, a front side of the housing can be a display assembly. The heat dissipation assembly 3 can be arranged under the display assembly. The display assembly can be aligned vertically with the functional assembly 2. The heat of the functional assembly 2 can be dissipated naturally through the heat dissipation assembly 3 onto the display assembly. Of course, the display assembly can generate heat during operation as well. The temperature of the display assembly can rise quickly due to the self-generated heat and the heat from the functional assembly 2. In some load scenarios, the display assembly can first reach the threshold. To ensure the operational reliability of the display assembly, temperature control may need to be performed on the display assembly. A temperature control threshold of the display assembly can be lower than a temperature control threshold of the functional assembly 2. In the electronic device of the present disclosure, the temperature control of the housing 1 can be independent of the temperature control of the functional assembly 2.

The functional assembly 2 can be a chip or a micro-functional assembly that can generate heat in the electronic device. That is, the heat dissipation assembly 3 can be configured to transfer the heat of the chip to the display assembly. The electronic device can be further configured to monitor the temperature of the housing and the temperature of the functional assembly and provide feedback about the temperature of the housing and the temperature of the functional assembly to the control module. A maximum temperature of the housing can be estimated through a board Negative Temperature Coefficient (NTC), while the temperature of the functional assembly can be monitored by a temperature sensor within the functional assembly. In addition, the heat dissipation assembly 3 can move away from the housing 1 to cause the heat dissipation assembly 3 to be away from the housing 1 to increase the gap therebetween. The heat dissipation assembly 3 can also move toward the housing 1 to cause the heat dissipation assembly 3 to be closer to the housing 1 to decrease the gap therebetween.

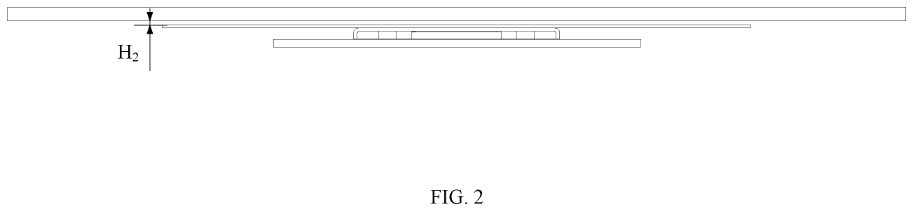

In addition, the feedback on the temperature of the housing and the temperature of the functional assembly can include a first feedback when the temperature of the housing reaches the first threshold and the temperature of the functional assembly does not reach a second threshold, a second feedback when the temperature of the functional assembly reaches the second threshold and the temperature of the housing does not reach the first threshold, and a third feedback when the temperature of the housing does not reach the first threshold and the temperature of the functional assembly does not reach the second threshold. When the feedback is the first feedback, the housing can reach the threshold first. Then, the control module can control the heat dissipation assembly 3 to move away from the housing 1 to cause the gap between the heat dissipation assembly 3 and the housing 1 to increase (gap H2 in FIG. 2 between the heat dissipation assembly 3 and the housing 1 being greater than gap H1 in FIG. 1 between the heat dissipation assembly 3 and the housing 1). Thus, the thermal resistance from the functional assembly 2 to the housing can be increased to cause the heat transferred to the housing 1 to be reduced or slowed down. Then, the temperature of the housing can be adaptively lowered to improve the user experience and avoid the limitation of the performance of the functional assembly. When the feedback is the second feedback, the temperature of the functional assembly can first reach the threshold, the control module can control the heat dissipation assembly 3 to move toward the housing 1 to cause the gap between the heat dissipation assembly and the housing 1 to decrease (e.g., gap H1 in FIG. 1 between the heat dissipation assembly 3 and the housing 1 being smaller than gap H2 in FIG. 2 between heat dissipation assembly 3 and the housing 1). Then, the thermal resistance from the functional assembly 2 to the housing 1 can be reduced to cause the temperature of the functional assembly to adaptively decrease, which avoids triggering the functional assembly to perform temperature control and reduce the frequency. When the feedback is the third feedback, the functional assembly temperature may need to be within a specific range, and the housing can satisfy the user experience. Then, the control module can be configured to control the heat dissipation assembly to stay still to maintain the gap between the heat dissipation assembly 3 and the housing 1 unchanged.

That is, when the current electronic device operates in different scenarios, one of the temperature of the functional assembly and the temperature of the housing can reach the threshold first to further bring a corresponding problem. Thus, the electronic device of the technical solution can include the heat dissipation assembly 3 that is movable relative to the housing 1. The control module can control the heat dissipation assembly 3 to move correspondingly relative to the housing 1 according to the feedback when one of the temperature of the functional assembly and the temperature of the housing reaches the threshold first. Thus, the gap between the heat dissipation assembly 3 and the housing 1 can change correspondingly to cause the thermal resistance from the heat dissipation assembly 3 to the housing 1 to change correspondingly. Thus, the temperature of the housing can be adaptively lowered to be lower than the threshold of the housing 2, or the temperature of the functional assembly can be adaptively lowered to be lower than the threshold of the functional assembly 2. That is, the temperature of the housing and the temperature of the functional assembly can be dynamically maintained to be lower than the threshold of the housing and the threshold of the temperature of the functional assembly, which solves the problem brought when the temperature of the functional assembly or the temperature of the housing reaches the threshold.

According to the technical solution, the electronic device of embodiments of the present disclosure can include the heat dissipation assembly that is movable relative to the housing. The control module can control the heat dissipation assembly to move correspondingly relative to the housing according to the feedback when one of the temperature of the functional assembly and the temperature of the housing reaches the threshold. Thus, the gap between the heat dissipation assembly and the housing can change correspondingly to cause the thermal resistance from the functional assembly to the housing to change correspondingly. Then, the temperature of the housing can be adaptively lowered to be lower than the threshold of the temperature of the housing, or the temperature of the functional assembly can be adaptively lowered to be lower than the threshold of the temperature of the functional assembly. That is, the temperature of the housing and the temperature of the functional assembly can be facilitated to be maintained lower than the threshold of the temperature of the housing and the threshold of the temperature of the functional assembly to solve the problem brought when the temperature of the functional assembly or the temperature of the housing reaches the threshold of the temperature of the functional assembly or the threshold of the temperature of the housing.

In the technical solution, as mentioned above, the control module can be configured to control the heat dissipation assembly 3 to move away from the housing 1 under the first feedback to increase the gap to increase the thermal resistance from the functional assembly 2 to the housing 1. Thus, the temperature of the housing can be appropriately lowered, and the temperature of the functional assembly can be appropriately increased to improve the user experience and avoid limiting the performance of the functional assembly. The first feedback can at least correspond to the temperature of the housing reaching the first threshold, and the temperature of the functional assembly being smaller than the second threshold. The first threshold can be the temperature control threshold of the housing 1. The second threshold can be the temperature control threshold of the functional assembly 2.

The control module can be further configured to control the heat dissipation assembly 3 to move toward the housing 1 under the second feedback to reduce the gap to decrease the thermal resistance from the functional assembly 2 to the housing 1. Thus, the temperature of the functional assembly can be appropriately lowered, and the temperature of the housing can be appropriately increased to avoid triggering the functional assembly to perform temperature control and reduce the frequency. The second feedback can at least correspond to the temperature of the functional assembly being greater than or equal to the second threshold, and the temperature of the housing being smaller than the first threshold.

In some embodiments, the housing 1 can operate under different load scenarios. Different first thresholds can be configured for each of the load scenarios. That is, the first threshold can be different when the housing 1 is in different load scenarios. For example, the first threshold of the housing 1 in a high-performance scenario can be 48° C. The first threshold in a game scenario can be 44° C. The first threshold in a video payback scenario can be 42° C. Thus, the feedback can be provided for whether the temperature of the housing reaches the first threshold, i.e., the feedback about whether the temperature of the housing reaches the first threshold corresponding to the current load scenario. Then, the accuracy of the feedback of the temperature of the housing can be ensured.

Further, as shown in FIG. 1, the heat dissipation assembly 3 includes a heat dissipation body and a drive module 34. The heat dissipation body is arranged between the housing 1 and the functional assembly 2.

The heat of the functional assembly 2 can be transferred to the housing 1 through the heat dissipation body. The heat dissipation body can have a gap with the housing 1. The heat dissipation body can move relative to the housing 1.

The drive module 34 can be configured to respond to the control signal of the control module to drive the heat dissipation body to move relative to the housing 1 to change the gap. The control signal can be issued by the control module based on the feedback of the temperature of the housing and the temperature of the functional assembly.

The heat dissipation body can move away from the housing 1 to enlarge the gap and move toward the housing 1 to reduce the gap. The control signal can include a first control signal, a second control signal, and a third control signal. The first control signal can be a control signal issued by the control module based on the first feedback. Then, the drive module 34 can drive the heat dissipation body to move away from the housing 1 to enlarge the gap. The thermal resistance from the functional assembly 2 to the housing 1 can be increased, and the temperature of the housing can be adaptively lowered. The second control signal can be a control signal issued by the control module based on the second feedback. Then, the drive module 34 can drive the heat dissipation body to move toward the housing 1 to reduce the gap. The thermal resistance from the functional assembly 2 to the housing 1 can be reduced, and the temperature of the functional assembly can be appropriately lowered. The third control signal can be a control signal issued by the control module based on the third feedback. Then, the drive module 34 may not drive the heat dissipation body, and the gap can stay unchanged.

That is, the heat dissipation assembly 3 can include a body member and a drive member. The drive member can respond to the corresponding control signal issued by the control module based on the corresponding feedback to drive the body member to move relative to the housing 1 (away from or toward). The thermal resistance from the functional assembly 2 to the housing 1 can be correspondingly adjusted to cause one of the temperature of the functional assembly or the temperature of the housing that reaches the threshold first to be appropriately lowered to ensure user experience or avoid triggering the functional assembly to perform temperature control and reduce the frequency. Then, the temperature of the housing and the temperature of the functional assembly can be dynamically adjusted to cause the temperature of the housing or the temperature of the functional assembly to be lowered appropriately once reaching the respective threshold.

Further, as shown in FIG. 1, the heat dissipation body at least includes a first heat dissipation body 31 and a second heat dissipation body 32.

The first dissipation body 31 and the second heat dissipation body 32 are stacked on the functional assembly 2. The second heat dissipation body 32 has a gap with the housing 1. The second heat dissipation body 32 can move relative to the housing 1.

The drive module 34 can be configured to respond to the control signal to drive the second heat dissipation body 32 to move relative to the housing 1 to change the gap.

The second heat dissipation body 32 can move away from the housing 1 to enlarge the gap and toward the housing 1 to reduce the gap.

The drive module 34 can respond to the first control signal to drive the second heat dissipation body 3 to move away from the housing 1 to enlarge the gap. Thus, the thermal resistance from the functional assembly 2 to the housing 1 can be increased, and the temperature of the housing can be appropriately lowered. In this process, the second heat dissipation body 32 can compress the first heat dissipation body 31. The first heat dissipation body 31 can be elastic and compressible.

The drive module 34 can also respond to the second control signal to drive the second heat dissipation body 3 to move toward the housing 1 to reduce the gap. Thus, the thermal resistance from the functional assembly 2 to the housing 1 can be reduced, and the temperature of the functional assembly can be appropriately lowered. The drive module 34 can further respond to the third control signal and not drive the second heat dissipation body 32. Thus, the gap can stay unchanged. In addition, as shown in FIG. 1, the heat dissipation body further includes a third heat dissipation body 33. The first heat dissipation body 31, the second heat dissipation body 32, and the third heat dissipation body 33 can be stacked in sequence on the top of the functional assembly 2. That is, the heat dissipation body can include a plurality of heat dissipation bodies stacked on the top of the functional assembly 2. The drive module can respond to the corresponding control signal to drive the middle heat dissipation body to perform the corresponding movement. Thus, the heat dissipation body can be prevented from compressing the functional assembly 2 when moving away from the housing 1. With a multi-layer heat dissipation structure, the heat dissipation effect of the functional assembly 2 can be improved.

As shown in FIG. 2, the drive module 34 responds to the first control signal to drive the second heat dissipation body 32 to move downward, away from the housing 1. Then, the first heat dissipation body 31 is compressed, and the third heat dissipation body 33 moves downward together with the second heat dissipation body 32 to cause the air gap between the heat dissipation body and the housing 1 to increase (e.g., H2 in FIG. 2). Then, the heat generated by the functional assembly 2 can be primarily transferred through the first heat dissipation body 31, the second heat dissipation body 32, the third heat dissipation body 33, and the air gap to the housing 1. Since the air gap is increased, the thermal resistance from the functional assembly 2 to the housing 1 can be increased to cause the temperature of the housing to be appropriately lowered.

As shown in FIG. 1, the drive module 34 can also respond to the second control signal to drive the second heat dissipation body 32 to move upward toward the housing 1. Then, the third heat dissipation body 33 moves upward together with the second heat dissipation body 32 to reduce the air gap between the heat dissipation body and the housing 1 (e.g., H1 in FIG. 1). Then, the heat generated by the functional assembly 2 can be primarily transferred through the first heat dissipation body 31, the second heat dissipation body 32, the third heat dissipation body 33, and the air gap to the housing 1. Since the air gap is reduced, the thermal resistance from the functional assembly 2 to the housing 1 can be reduced. Thus, the temperature of the functional assembly can be lowered appropriately.

In some embodiments, the first heat dissipation body 31 can be elastic and compressible.

The drive module 34 can be configured to respond to the first control signal issued by the control module under the first feedback to drive the second heat dissipation body 32 to move away from the housing 1 and compress the first heat dissipation body 31 to prevent the heat dissipation body from compressing the functional assembly 2 when being driven by the drive module 34 and avoid the moving interference between the heat dissipation assembly 3 and the functional assembly 2. In FIG. 2, the first heat dissipation body 31 has been compressed. In FIG. 1, the first heat dissipation body 31 is not compressed. The thickness of the first heat dissipation body 31 in FIG. 2 is greater than the thickness of the first heat dissipation body in FIG. 1. The first feedback can at least correspond to the temperature of the housing reaching the first threshold, and the temperature of the functional assembly being smaller than the second threshold. When the drive module 34 responds to the second control signal to drive the second heat dissipation body 32 to move toward the housing 1 and release the compression to the first heat dissipation body 31, the first heat dissipation body 31 can restore elastically based on an elastic force. Thus, the three heat dissipation bodies can maintain an in-contact transfer relationship between each two heat dissipation bodies.

In some embodiments, as shown in FIG. 1, the electronic device of embodiments of the present disclosure includes a carrier 4. The carrier 4 can be arranged in the housing 1. The functional assembly 2 can be arranged at the carrier 4.

The drive module 34 is arranged at the carrier 4 and includes a retractable end configured to retract along an opposite direction of the housing 1 and the functional assembly 2.

A side of the second heat dissipation body 32 away from the housing 1 is connected to the retractable end of the drive module 34.

The carrier 4 can be used as a substrate of the functional assembly 2, e.g., a PCB board. The drive module 34 can be a retractable module. The retractable end can face the housing 1 and can be connected to one side of the second heat dissipation body 32 away from the housing 1. The drive module 34 can respond to the corresponding control signal to drive the second heat dissipation body 32 to move along the opposite direction of the housing 1 and the functional assembly 2. To ensure the stability of the movement of the second heat dissipation body 32, as shown in FIG. 1, at least two drive modules 34 are provided and symmetrically distributed on two sides of the functional assembly 2.

In addition, as shown in FIG. 1, the first heat dissipation body 31 is a thermal pad (electric and compressible). The second heat dissipation body 32 can be a shield cover. The shield cover includes a top cover member and a side member. The second heat dissipation body 32 can be graphite or graphene. The thermal pad, the top cover member, and the graphite or graphene are stacked in sequence at the top of the functional assembly 2. The side member is arranged between the circumference of the top cover member and the carrier 4 to form an empty chamber between the shield cover and the carrier 4. The top of the side member can be connected to the boundary of the top cover. The functional assembly 2 and the two driven module 34 can be arranged in the empty chamber. The retractable ends of the two drive modules 34 can be connected to the inner side of the top cover member. That is, in the technical solution, the shield cover and the carrier 4 can form a coverage on the functional assembly 2 to facilitate transferring the heat of the functional assembly 2 to the housing 1 and avoid the heat dissipation of the functional assembly 2. The drive module 34 can respond to the first control signal to drive the top cover member to move away from the housing 1 (e.g., downward) and compress the thermal pad. In the process, to ensure the movement of the shield cover without interference, the bottom end of the side member can elastically compress the top of the carrier 4. That is, the top of the carrier 4 in contact with the bottom of the side member can also be elastic and compressible. Thus, the thermal pad can be a high thermal pad (K≥6w/(m*k)) to ensure good heat transfer performance for the thermal pad.

In addition, to facilitate accurate drive and miniaturized design of the drive module 34. In some embodiments, the drive module 34 can include a voice coil motor. The DC current of the voice coil motor can be in a one-to-one correspondence with a displacement of the voice coil motor. That is, the size of the DC of the voice coil motor can be controlled through the control module to control the displacement of the voice coil motor. Thus, the up and down displacement of the shield cover can be controlled. Since the voice coil motor is arranged on a side of the functional assembly 2 (e.g., chip), the voice coil motor may need to be high temperature resistant and cannot exceed the highest temperature of the functional assembly 2. The voice coil motor can be packaged with a high-temperature resistant material, a suitable high temperature can be 90° C. to 120° C. when the voice coil motor is not in use. The highest temperature of the functional assembly 2 (e.g., chip) can be 115° C. (hardware shutdown threshold). Normally, the temperature may not exceed 105° C./110° C. (software reset or shutdown threshold). Thus, the area where the voice coil motor is located can normally be smaller than 90° C.

Furthermore, the drive module 34, can be configured to respond to the control signal to drive the heat dissipation body to move a corresponding displacement along a corresponding direction based on a preset relationship among a difference between the temperature of the housing and the first threshold, a difference between the temperature of the functional assembly and the second threshold, and the displacement of the heat dissipation body.

In addition to the above first feedback, the second feedback, and the third feedback, the feedback on the temperature of the housing and the temperature of the functional assembly can also include a feedback on a first temperature difference and a second temperature difference. The first temperature difference can be the difference between the temperature of the housing and the first threshold, i.e., can be equal to the first threshold minus the temperature of the housing. The second temperature difference can be the difference between the temperature of the functional assembly and the second threshold, i.e., can be equal to the second threshold minus the temperature of the functional assembly. The first feedback and the first temperature difference feedback can be provided together, and the second feedback and the second temperature difference feedback can be provided together. That is, the drive module 34 can be configured to respond to the control signal to drive the heat dissipation body to move along a corresponding direction relative to the housing 1. For example, the drive module 34 can be configured to respond to the first control signal to drive the heat dissipation body to move away from the housing 1. The moving direction can be the direction away from the housing 1. The drive module 34 can be further configured to respond to the second control signal to drive the heat dissipation body to move toward the housing 1. The moving direction can be the direction approaching the housing 1. The drive module 34 can be further configured to drive the heat dissipation body to move a corresponding displacement along a corresponding direction based on the preset relationship among the first temperature difference, the second temperature difference, and the heat dissipation body. For example, under the first control signal, the drive module 34 can be further configured to drive the heat dissipation body to move away from the housing for a corresponding displacement based on the preset relationship among the first temperature difference, the second temperature difference, and the displacement of the heat dissipation body to cause the temperature of the housing to be appropriately lowered to be lower than the threshold of the temperature of the housing and also cause the temperature of the functional assembly to appropriately rise without exceeding the threshold of the temperature of the functional assembly. Under the second control signal, the drive module 34 can be further configured to drive the heat dissipation body to move toward the housing 1 for a corresponding displacement based on the preset relationship among the first temperature difference, the second temperature difference, and the heat dissipation body displacement to cause the temperature of the functional assembly to be appropriately lowered to be lower than the threshold of the temperature of the functional assembly and cause the temperature of the housing to appropriately rise without exceeding the threshold of the temperature of the housing. That is, the control module can be configured to control the moving direction (an away from direction or a toward direction) of the heat dissipation assembly 3 relative to the housing 1 based on one of the temperature of the housing and the temperature of the functional assembly reaching the respective threshold first. The drive module can be further configured to control the moving displacement of the heat dissipation assembly 3 based on the feedback on the difference between the one of the temperature of the housing and the temperature of the functional assembly reaching the threshold first and the threshold to cause the one of the temperature of the housing and the temperature of the functional assembly to be appropriately lowered to be lower than the respective threshold and the other one of the temperature of the housing and the temperature of the functional assembly to appropriately rise without reaching the respective threshold. In addition, to better understand the above solution, the voice coil motor is taken as an example for description.

According to the model of the voice coil motor, an appropriate current size and a displacement range can be selected to match the first temperature difference ΔTcase and the second temperature difference ΔTj that are monitored.

Based on the above, the first temperature difference ΔTcase can be the difference between the temperature of the housing and the first threshold, i.e., can be equal to the first threshold minus the temperature of the housing. Based on the above, the housing 1 can have different first thresholds in different load scenarios, accordingly, ΔTcase=48° C.−Tc (performance scenario), ΔTcase=44° C.−Tc (gaming scenario), and ΔTcase=42° C.−Tc (video playback scenario), where Tc is the temperature of the housing and is obtained by estimation through the board NTC.

The second temperature difference ΔTj can be the difference between the temperature of the functional assembly and the second threshold, i.e., can be equal to the second threshold minus the temperature of the functional assembly, accordingly, ΔTj=90° C.−Tjmax, where Tjmax is the temperature of the functional assembly, which can be monitored by the temperature monitoring module within the functional assembly 2.

For example, the selected drive current of the voice coil motor can be 24 mA, with a reference current of 74 mA, and a maximum displacement (moving distance) of 0.22 mm. That is, when the voice coil motor operates at the current ranging from 24 mA to 74 mA, the corresponding displacement can range from 0 to 0.22 mm.

The displacement and the current of the voice coil motor can form a one-to-one correspondence. Then, the first temperature difference ΔTcase and the second temperature difference ΔTj can be matched.

Assume that the displacement is 20step, and correspondingly, 0.22/20=11 μm, and (74−24)/20=2.5mA, that is, 1 step corresponds to a current change amount of 2.5 mA and a displacement change amount of 11 μm. Thus, the displacement of 0.22 mm can be controlled by dividing into ±0.11 mm. Of course, the displacement can also be divided into other step counts.

When ΔTj>0 and ΔTcase>0 (i.e., the third feedback), the control module can control the voice coil motor to maintain the current state without expansion or contraction, i.e., keep the gap unchanged.

When ΔTj>0 and ΔTcase<0 (i.e., the first feedback), the control module can control the voice coil motor to compress to cause the shield cover to move downward to enlarge the air gap and the thermal resistance. Thus, the temperature of the housing can be appropriately lowered, and the temperature of the functional assembly can appropriately rise to improve the user experience.

When ΔTj<0 and ΔTcase>0 (i.e., the second feedback), the control module can control the voice coil motor to extend to cause the shield cover to move upward to reduce the air gap and thermal resistance. Thus, the temperature of the functional assembly can be appropriately lowered, and the temperature of the housing can appropriately rise.

When ΔTj>0 and ΔTcase<0 (i.e., the first feedback), the amount of the compression displacement for the voice coil motor can be described in the following example.

Assume that based on a hardware product type, when the voice coil motor moves 11 μm (i.e., one step), ΔTj can change by 0.5° C., and ΔTcase can change by 0.2° C.

In a certain load scenario, ΔTj=90° C.−86°C.=4° C., and ΔTcase=48° C.−49°C.=−1° C.

Correspondingly, 1/0.2=5 steps, 4/0.5=8 steps, the temperature of the housing needs to be maintained below the first threshold 48° C. after the adjustment and fewer steps may be selected. That is the displacement can at least be selected as min(5,8)=5step.

That is, the voice coil motor can at least compress for 5step (or 6step), the shield cover can move downward by 0.55 μm, the temperature of the housing can at least be lowered by 1° C. to be lower than 48° C. The temperature of the functional assembly can at least rise by 2.5° C. to be greater than 88.5° C. but lower than the threshold 90° C. Thus, the room of temperature rise can be transferred.

Embodiments of the present disclosure further provide a temperature control method applied to an electronic device. The electronic device can include a functional assembly 2 arranged in the housing 1 of the electronic device and a heat dissipation assembly 3.

The heat dissipation assembly 3 can be configured to transfer the heat of the functional assembly 2 to the housing 1. The heat dissipation assembly 3 can have a gap with the housing 1. The heat dissipation assembly 3 can move relative to the housing 1 to change the gap.

The temperature control method can include monitoring the temperature of the housing and the temperature of the functional assembly, when the feedback on the temperature of the housing reaching the first threshold is provided, and the temperature of the functional assembly is smaller than the second threshold, control the heat dissipation assembly 3 to move away from the housing 1 or trigger the housing 1 to perform temperature control to maintain the temperature of the housing to be lower than the first threshold, and when the feedback on the temperature of the functional assembly being greater than or equal to the second threshold, and the temperature of the housing is smaller than the first threshold, controlling the heat dissipation assembly 3 to move toward the housing 1 or adjusting the operation state of the functional assembly 2 to maintain the temperature of the functional assembly to be lower than the second threshold.

The electronic device can monitor the temperature of the housing and the temperature of the functional assembly. In the temperature control method, when the feedback on the temperature of the housing reaching the first threshold is provided, the temperature of the functional assembly can be smaller than the second threshold (i.e., the first feedback). In practical applications, the heat dissipation assembly 3 can be controlled by the control module of the electronic device to move away from the housing 1 to enlarge the gap between the heat dissipation assembly 3 and the housing 1. The thermal resistance from the functional assembly 2 to the housing 1 can be enlarged. The temperature of the housing can be appropriately lowered to maintain the temperature of the housing to be lower than the first threshold, or the housing 1 can be triggered to perform the temperature control to maintain the temperature of the housing to be lower than the first threshold to ensure the user experience.

When the feedback on the temperature of the functional assembly being greater than or equal to the second threshold is provided, the temperature of the housing can be smaller than the first threshold (i.e., the second feedback), the heat dissipation assembly 3 can be controlled to move toward the housing 1 to reduce the gap between the heat dissipation assembly 3 and the housing 1. The thermal resistance from the functional assembly 2 to the housing 1 can be reduced. The temperature of the functional assembly can be appropriately lowered to maintain the temperature of the functional assembly to be lower than the second threshold, or the operation state of the functional assembly 2 can be adjusted. That is, temperature control can be performed on the functional assembly 2 to maintain the temperature of the functional assembly to be not lower than the second threshold to avoid triggering the functional assembly to perform the temperature control and reduce the frequency. That is, in the temperature control method of the present disclosure, the temperature of the housing and the temperature of the functional assembly can be dynamically maintained to be lower than the respective threshold. Thus, the user experience can be maintained while the performance of the functional assembly is maintained.

In the technical solution of the present disclosure, controlling the heat dissipation assembly 3 to move away from the housing 1 can include controlling the heat dissipation assembly 3 to move a corresponding displacement way from the housing 1. The preset relationship can be provided for the difference among the displacement, the difference between the temperature of the housing and the first threshold, and the difference between the temperature of the functional assembly and the second threshold to cause the heat dissipation assembly 3 to ensure that the temperature of the housing is appropriately lowered to be lower than the first threshold and ensure that the temperature of the functional assembly rises appropriately without reaching the second threshold. For the present relationship among the displacement, the difference between the temperature of the housing and the first threshold, and the difference between the temperature of the functional assembly and the second threshold, reference can be made to the above description, which is not repeated here.

Similarly, controlling the heat dissipation assembly 3 to move toward the housing 1 can include controlling the heat dissipation assembly to move towards the housing 1 for a corresponding displacement. The present relationship among the displacement, the difference between the temperature of the housing and the first threshold, and the difference between the temperature of the functional assembly and the second threshold can be provided to cause the heat dissipation assembly 3 to ensure that the temperature of the functional assembly is appropriately lowered to be lower than the second threshold and ensure that the temperature of the housing rises appropriately without reaching the first threshold.

Embodiments of the present disclosure are described in a progressive manner. Each embodiment focuses on differences from other embodiments. The same or similar parts of embodiments of the present disclosure can refer to each other.

The description of embodiments of the present disclosure can allow those skilled in the art to implement or use the present disclosure. Various modifications can be made to embodiments of the present disclosure and can be obvious to those skilled in the art. The general principle defined in the specification can be implemented in other embodiments without departing from the spirit or scope of the present disclosure. Thus, the present disclosure is not limited to the embodiments of the present specification but should conform to the widest scope consistent with the principle and novel features of the present disclosure.

What is claimed is:

1. An electronic device comprising:
a housing;
a functional assembly arranged in the housing;
a heat dissipation assembly configured to transfer heat of the functional assembly to the housing, having a gap with the housing, and moving relative to the housing to cause the gap between the heat dissipation assembly and the housing to change; and
a control module configured to control the heat dissipation assembly to move to adjust the gap between the heat dissipation assembly and the housing based on a feedback of a temperature of the housing and a temperature of the functional assembly.

2. The device according to claim 1, wherein the control module is further configured to:
under a first feedback, control the heat dissipation assembly to move away from the housing to enlarge the gap, the first feedback at least corresponding to the temperature of the housing reaching a first threshold and the temperature of the functional assembly being smaller than a second threshold; and
under a second feedback, control the heat dissipation assembly to move toward the housing to reduce the gap, the second feedback corresponding to the temperature of the functional assembly being greater than or equal to the second threshold, and the temperature of the housing being smaller than the first threshold.

3. The device according to claim 2, wherein the housing operates in different load scenarios, and each load scenario corresponds to a different first threshold.

4. The device according to claim 1, wherein the heat dissipation assembly includes:
a heat dissipation body arranged between the housing and the functional assembly, including a gap with the housing, being movable relative to the housing, and the heat of the functional assembly being transferred to the housing through the heat dissipation body; and
a drive module configured to respond to a control signal of the control module to drive the heat dissipation body to move relative to the housing to change the gap, the control signal being issued by the control module based on the feedback of the temperature of the housing and the temperature of the functional assembly.

5. The device according to claim 4, wherein the heat dissipation body includes at least a first heat dissipation assembly and a second heat dissipation assembly, wherein:
the first heat dissipation assembly and the heat dissipation assembly are stacked on top of the functional assembly, the second heat dissipation assembly has a gap with the housing and being movable relative to the housing; and
the drive module configured to respond to the control signal to drive the second heat dissipation assembly to move relative to the housing to change the gap.

6. The device according to claim 5, wherein:
the first heat dissipation assembly is compressible; and
the drive module is further configured to respond to a first control signal issued by the control module under the first feedback to drive the second heat dissipation body to move away from the housing and compress the first heat dissipation body, the first feedback at least corresponding to the temperature of the housing reaching the first threshold, and the temperature of the functional assembly being smaller than the second threshold.

7. The device according to claim 5, further comprising a carrier arranged in the housing, the functional assembly being arranged at the carrier, wherein:
the drive module is arranged at the carrier and includes a retractable end configured to extend and retract along an opposite direction of the housing and the functional assembly; and
a side of the second heat dissipation body facing away from the housing is connected to the retractable end of the drive module.

8. The device according to claim 4, wherein the drive module is configured to respond to the control signal to drive the heat dissipation body to move along a corresponding direction for a corresponding displacement based on a preset relationship among a difference between the temperature of the housing and the first threshold, a difference between the temperature of the functional assembly and the second threshold, and the displacement of the heat dissipation body.

9. A temperature control method applied to an electronic device comprising:
monitoring a temperature of the housing and a temperature of the functional assembly;
in response to the temperature of the housing reaching a first threshold, and the temperature of the functional assembly being smaller than a second threshold, controlling a heat dissipation assembly to move away from a housing of the electronic device or trigger the housing to perform temperature control to maintain the temperature of the housing to be lower than the first threshold; and
in response to the temperature of the functional assembly being greater than or equal to the second threshold, and the temperature of the housing being smaller than the first threshold, controlling the heat dissipation assembly to move toward the housing or adjust an operation state of the functional assembly to maintain the temperature of the functional assembly to be lower than the second threshold.

10. The method according to claim 9, wherein controlling the heat dissipation assembly moving away from the housing includes:
controlling the heat dissipation assembly to move for a corresponding displacement away from the housing, a preset relationship among a difference between the temperature of the housing and the first threshold, a difference between the temperature of the functional assembly and the second threshold, and the displacement being provided.

11. The method according to claim 9, wherein controlling the heat dissipation assembly moving away from the housing includes:
under a first feedback, controlling the heat dissipation assembly to move away from the housing to enlarge the gap, the first feedback at least corresponding to the temperature of the housing reaching a first threshold and the temperature of the functional assembly being smaller than a second threshold; and
under a second feedback, controlling the heat dissipation assembly to move toward the housing to reduce the gap, the second feedback corresponding to the temperature of the functional assembly being greater than or equal to the second threshold, and the temperature of the housing being smaller than the first threshold.

12. The method according to claim 11, wherein the housing operates in different load scenarios, and each load scenario corresponds to a different first threshold.
